(19) United States
(12) Patent Application Publication
(10) Pub. No.: US 2016/0121736 A1
(43) Pub. Date: May 5, 2016

(54) EVSE SHORTED CABLE PROTECTION METHOD

(71) Applicant: SCHNEIDER ELECTRIC USA, INC., Palatine, IL (US)

(72) Inventors: Kevin M. JEFFERIES, Raleigh, NC (US); Benjamin W. EDWARDS, Rolesville, NC (US); Matthew L. WHITE, Raleigh, NC (US); Konstantin A. FILIPPENKO, Raleigh, NC (US); Richard K. WEILER, Raleigh, NC (US)

(21) Appl. No.: 14/529,793

(22) Filed: Oct. 31, 2014

(51) Int. Cl. B60L 11/18; G01R 31/08

(52) U.S. Cl. CPC B60L 11/1809; G01R 31/086

(57) ABSTRACT

A method detects a shorted charging cable of an electric vehicle charging station. A charging cable of the electric vehicle charging station is determined to not be connected to an electric vehicle. An impedance test may then be performed between conductors of the charging cable while not connected to an electric vehicle. A contactor between a source of electrical power and the conductors is prevented from closing, in response to detecting a short between the conductors, and a warning signal is output. The impedance test is disabled in response to receiving a signal indicating that the charging cable has become connected to an electric vehicle, so as to not interfere with normal charging. In this manner, by detecting a short circuit in the charging cable before the contactors are closed, the contactor's contacts are prevented from becoming welded closed by a short circuit in the charging cable.

### BACKGROUND OF THE INVENTION

1. Field of the Invention

The invention disclosed relates to electric vehicle supply equipment.

2. Discussion of the Related Art

Plug-in electric vehicles (EVs), including all-electric cars, neighborhood electric vehicles and plug-in hybrids, are becoming a popular mode for personal transportation, in part because they are less expensive to operate and have a reduced carbon footprint. Electric vehicle charging stations, also called Electric Vehicle Supply Equipment (EVSE), provide power to an EV through a standardized interface. The most common interface is defined by industry standard SAE J1772. The interface includes defined control signals, ground, and a high ampere current path. In the Level 2 alternating current (AC) charging standard, the EVSE may provide up to 80A charging current to the connected EV.

The EVSE includes a relay or contactor to disconnect the power poles providing charging energy to the electric vehicle (EV) from the incoming power provided to the EVSE. Electromechanical contacts in the relay or contactor are subject to specific failure modes, for example the welding of contacts. Contact welding can occur when the contacts are subjected to sufficient current to cause the contact material to melt, such as when the load connection experiences a short circuit. Such situations may occur in the charging cable, which typically includes five or more meters of cable exposed to the environment. The charging cable may be severely bent, dropped, pulled on and run over by a vehicle. Such misuse is expected and is difficult to avoid, since the charging cable has to be long enough to accommodate different types of vehicles.

Preventive measures can be taken to protect relay or contactor contacts from welding under specific conditions, for example coordination can be applied with upstream protective devices, such as fuses or circuit breakers. However, replacing fuses or resetting breakers, requires proper diagnosis of the fault and clearing of the fault by authorized maintenance personnel. Until such maintenance is performed, the welded contacts of the relay or contactor leave the EVSE inoperable and unusable.

Present solutions are available for detecting short circuits, but have not been applied to protecting EVSE relay or contactor contacts from welding.

### SUMMARY OF THE INVENTION

The subject invention uses short circuit detection in an EVSE, before main power contactors in the EVSE are closed, to prevent power from being delivered to the charging handle when a fault is detected in the charging cable. The subject invention does not require that the charging cable be connected to an EV, in order to perform a test. An impedance measuring circuit and control electronics are included in the EVSE to measure the resistance between the cable conductors before the cable is connected to an EV. The main current carrying conductors in the cable are the L1, L2 or N, and ground conductors. The resistance between any two of these conductors is measured by the impedance measuring circuit. If the measured resistance is less than a threshold resistance value, the control electronics identifies that a short circuit condition exists between the two conductors being tested. In response, the control electronics outputs a protection signal to the contactors in the EVSE, to prevent them from being closed. A warning signal may also be generated, to notify the user that a short has been detected in the charging cable.

The impedance measuring circuit includes a multiplexer controlled by the control electronics, to sequentially connect pairs of the L1, L2 or N, and ground conductors for resistance measurement. The control electronics may control the impedance measurement circuit to perform an impedance measurement between sequentially selected pairs of conductors of the charging cable. The measurement may be repeated at intervals to monitor the integrity of the conductors over time. The control electronics may be configured to output the identity of shorted conductors for appropriate maintenance action. The control electronics may be configured to record the results of the impedance tests for pairs of the conductors, to compile a maintenance history. The control electronics may be configured to disable the impedance measurement circuit in response to receiving a signal indicating that the charging cable has become connected to an electric vehicle.

In this manner, by detecting a short circuit in the charging cable before the contactors are closed, the EVSE relay or contactor contacts are protected from being welded closed.

### BRIEF DESCRIPTION OF THE FIGURES

FIG. 1 is a functional block diagram of an example EVSE with an impedance measurement circuit in the EVSE, configured to measure impedance between different pairs of conductors of the charging cable while the charging cable is not connected to an electric vehicle.

FIG. 2 is a functional block diagram of an example impedance measurement circuit and control electronics in the EVSE, configured to sequentially perform impedance measurement between different pairs of conductors of the charging cable while the charging cable is not connected to an electric vehicle.

FIG. 3 is a functional block diagram of the example control electronics in the EVSE, including pilot signal measurement, microprocessor, and memory components.

### DETAILED DESCRIPTION OF EMBODIMENTS OF THE INVENTION

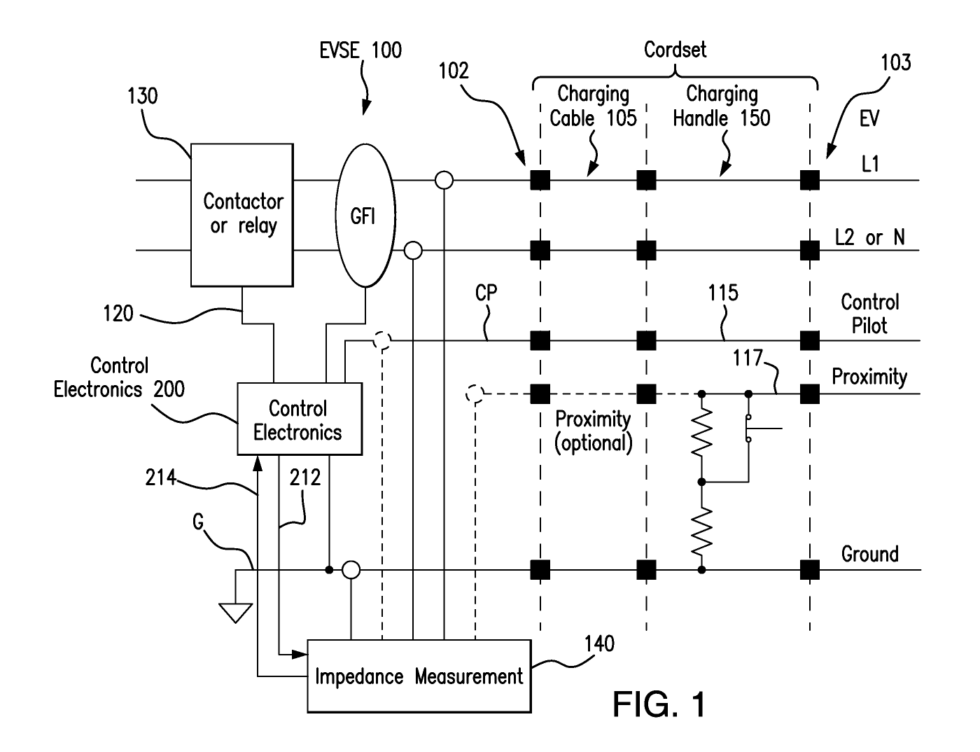

FIG. 1 is a functional block diagram of an example Electric Vehicle Supply Equipment (EVSE) 100 and a charging cable 105 connected from the charging output port 102 of the EVSE to the onboard input port 103 of the electric vehicle (EV). A charging handle 150 is connected to the opposite end of the cable from the EVSE and is configured to plug into the onboard input port 103 of the electric vehicle (EV), for charging operations. The charging cable 105 has two power conductors L1 and L2 or N (neutral), a ground conductor G, and a control pilot conductor 115. The power conductors L1 and L2/N receive power through a contactor or relay 130 in the EVSE. The control pilot conductor 115 in the charging cable 105 carries a control pilot signal CP that functions to verify to the EVSE that an EV is present and connected to the charging handle 150, for example as described in the SAE J1772 standard.

The charging cable 105 may be subjected to physical stresses during normal use by users who inadvertently pull on, drop, or run over the cable. The charging cable 105 typically delivers up to 30 Amperes of current at approximately 208 or 240 volts when charging an EV. Any damaged section along the cable 105 having a low resistance between the current-carrying conductors L1 and L2/N or the ground conductor G, may conduct sufficient current to cause upstream contacts of the relay or contactor 130, to weld closed.

In an example embodiment of the invention, an impedance measurement circuit 140 is incorporated in the EVSE, to measure impedance between different pairs of the conductors L1, L2/N, and ground G of the charging cable 105. The impedance measurements are limited to occur only during periods when the charging cable 105 and its charging handle 150 are not connected to an EV, so as to not interfere with normal vehicle charging operations.

Control electronics 200 are also incorporated in the EVSE, including a sensing circuit connected to the control pilot conductor 115, to receive the control pilot signal CP. The control electronics 200 determines from the control pilot signal CP whether the charging handle 150 of the charging cable 105 is connected to an EV. The control electronics 200 is connected over line 212 to the impedance measurement circuit 140, to control the impedance measurement circuit 140 to conduct impedance measurements only during periods when the charging cable 105 and its charging handle 150 are not connected to an EV.

The control electronics 200 is connected over an input line 214 from the impedance measurement circuit 140. If the impedance measurement circuit 140 measures a low resistance between any pair of the current-carrying conductors L1 and L2/N or the ground conductor G, the impedance measurement circuit 140 sends an alert signal on line 214 to the control electronics 200, signaling that it has detected a short between two of the conductors. If an impedance measurement result is outside of acceptable limits, the impedance measurement circuit 140 signals that condition. The control electronics 200 may be configured to output the identity of shorted conductors for appropriate maintenance action.

The control electronics 200 is connected over line 120 to the contactor or relay 130. A protection circuit in the control electronics 200 is configured to send a protection signal over line 120 to the contactor or relay 130 in response to the impedance measurement circuit 140 detecting a short between the conductors. When the contactor or relay 130 receives the protection signal on line 120, it prevents closure of the contacts in the contactor or relay 130, preventing power to be applied from the power source to the conductors L1 and L2/N of the charging cable 105.

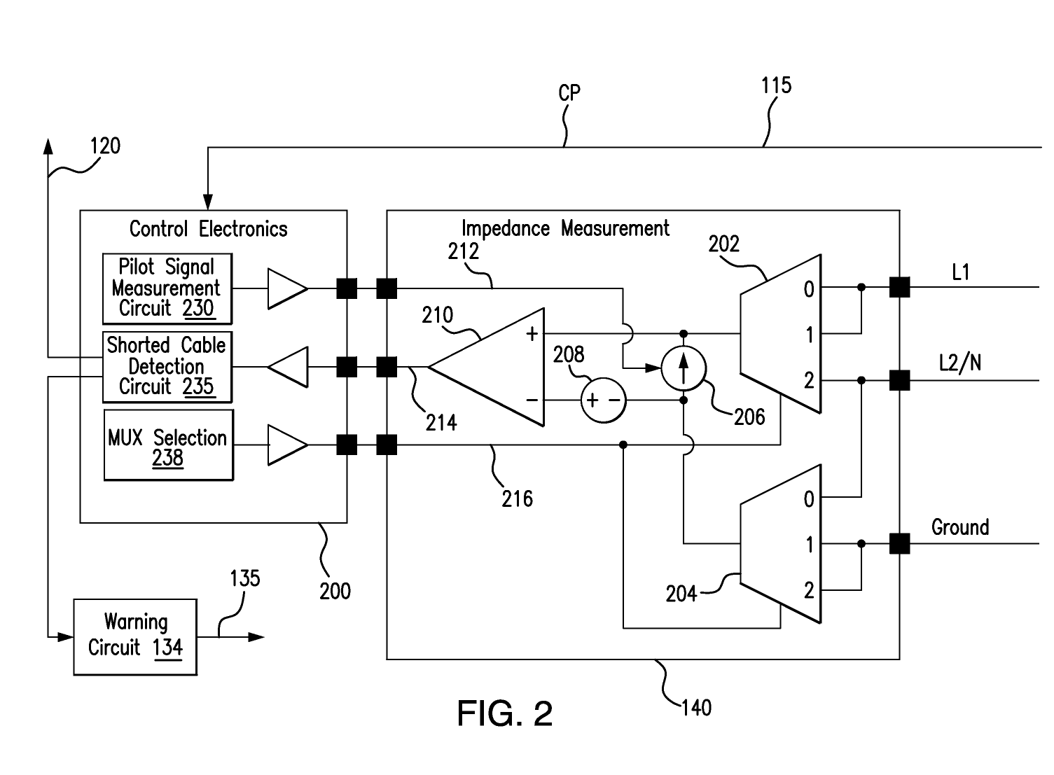

The control electronics 200 may include a warning circuit 134 (shown in FIG. 2), configured to output a warning signal 135 (shown in FIG. 2), to an annunciator such an LED display (not shown), in response to the impedance measurement circuit 140 detecting a short between the conductors L1 and L2/N or the ground conductor G. The warning circuit may output the identity of the shorted conductors, which may be displayed by LED lights on the EVSE or which may be sent in an email message. The warning circuit may output a notification on a mobile application to the owner of the EVSE for appropriate maintenance action. The same notification may be delivered to a service maintenance organization that may be responsible for the up-time of the EVSE.

In example embodiments of the invention, the impedance measurement circuit 140 may also measure and detect a short circuit condition in the control pilot conductor 115 or the proximity conductor 117. This may provide additional detection of conditions that might impair or prevent proper operation of the EVSE. The impedance measurement circuit 140 may be configured to detect a short circuit condition from L1 or L2/N to the control pilot conductor 115 or the proximity conductor 117 as a short circuit to ground, due to a relatively low impedance to ground of these conductors.

The proximity conductor 117 is connected to a proximity switch in the charging handle 150, which detects initial insertion of the charging handle 150 into the vehicle inlet, before any electrical contact is established, for example as described in the SAE J1772 standard. In an alternate example embodiment of the invention, the control electronics 200 may determine from the proximity conductor 117 whether initial insertion of the charging handle 150 into the vehicle inlet has occurred, before any electrical contact is established. In this alternate example embodiment, the control electronics 200 may control the impedance measurement circuit 140 to conduct impedance measurements only during periods when the charging handle 150 has not been initially inserted into the vehicle inlet.

FIG. 2 is a functional block diagram of the impedance measurement circuit 140 and the control electronics 200 incorporated in the EVSE. Control electronics 200 includes the pilot signal measurement circuit 230 that is a sensing circuit connected to the control pilot conductor 115, to receive the control pilot signal CP. The control electronics 200 is connected over line 212 to the impedance measurement circuit 140, to control the impedance measurement circuit 140 to conduct impedance measurements only during periods when the charging cable 105 and its charging handle 150 are not connected to an EV.

The impedance measurement circuit 140 includes for example a multiplexer circuit comprising multiplexer switches 202 and 204 that are configured to enable sequentially measuring impedance between different pairs of conductors L1, L2/N and ground G of the charging cable 150, while the charging cable is not connected to an EV. The impedance measurement checks the impedance between combinations of pairs of the conductors. Multiplexer switch 202 is connected to the L1 and L2/N conductors and multiplexer switch 204 is connected to the L2/N and ground G conductors. The MUX selection 238 of the control electronics 200, is connected over line 216 to the multiplexer switches 202 and 204, to enable sequentially performing an impedance test between different pairs of the conductors L1, L2/N and ground G of the charging cable 105, while the charging cable is not connected to an EV. This arrangement allows the control electronics 200 to control which combination of conductors L1, L2, and ground G the impedance measurement circuit 140 measures at any given time.

In alternate embodiments, the MUX selection 238 signal on line 216 may be generated by the control electronics 200 when the pilot signal measurement circuit 230 indicates that there is no connection to an EV. In example embodiments, other methods of impedance measurement may be used and other methods of selecting conductors to test may be used.

In an example embodiment, the impedance measurement circuit 140 includes a current source 206 connected between the output of multiplexer switch 202 and the output of multiplexer switch 204. The output of multiplexer switch 202 is connected to the plus side of the differential amplifier 210. The output of multiplexer switch 204 is connected through a voltage source, such as a battery, to the minus side of the differential amplifier 210. For a given combination of two of the conductors L1, L2/N and ground G, if there is no short between the two conductors, then no current flows through the current source 206 and the differential amplifier 210 does not out put an alert signal on line 214 to the control electronics 200. Alternately, if there is a short detected between the two conductors, then current flows through the current source 206 and the differential amplifier 210 outputs an alert signal on line 214 to the control electronics 200. The control electronics 200 may be configured to output the identity of shorted conductors for appropriate maintenance action. When the pilot signal measurement circuit 230 receives a control pilot signal CP indicating that an EV is connected, the pilot signal measurement circuit 230 sends a disabling signal on line 212 to the current source 206 to turn off the current source. In this manner, impedance measurements are not made when the charging cable 105 and its charging handle 150 are connected to an EV.

In example embodiments of the invention, the impedance measurement circuit 140 may be implemented using a voltage source or a current source. FIG. 2 depicts a current source and voltage comparison to a threshold, to detect the impedance being below a threshold. The threshold value may be set sufficiently high so that a short to the control pilot conductor 115 or the proximity conductor 117 will appear as a short to ground. For example, the threshold value may be set to indicate an impedance below 1 Megohm as a shorted conductor connection.

Control electronics 200 includes the shorted cable detection circuit 235 that is a protection circuit connected to the line 214 from the impedance measurement circuit 140. If the shorted cable detection circuit 235 receives an alert signal on line 214, it sends a protection signal over line 120 to the contactor or relay 130, to prevent closure of the contacts in the contactor or relay 130, preventing power to be applied from the power source to the conductors L1 and L2/N of the charging cable 105. In addition, the shorted cable detection circuit 235 may send the protection signal to the warning circuit 134. The shorted cable detection circuit 235 may also send the identity of the shorted conductors to the warning circuit 134, to be displayed by the warning circuit for appropriate maintenance action by the owner of the EVSE. This allows a display of the shorted cable detection status for every combination of conductors tested, to indicate the precise problem to the owner or operator of the EVSE. The control electronics 200 may test the impedance of the conductors of the cable 105 and record the detection status for every pair of the conductors as maintenance records. The measurement may be repeated at intervals to monitor the integrity of the conductors over time.

Based on the detection, the EVSE may take various actions. The EVSE may prevent a user from unlatching the charging handle 150 from the EVSE, if equipped with a locking mechanism. The EVSE may display an error message or otherwise indicate unavailability to potential users. The EVSE may indicate to the owner or operator, for example by email communications, that the EVSE is unavailable and requires maintenance.

In an example embodiment, the control pilot signal CP on the control pilot conductor 115 may be specified in the SAE J1772 standard. The standard specifies that the control pilot signal CP functions to verify that the electric vehicle EV is present and connected, permits energization/de-energization of the supply, transmits supply equipment current rating to the vehicle, monitors the presence of the equipment ground, and establishes vehicle ventilation requirements. The control pilot signal CP on the control pilot conductor 115 specified in the SAE J1772 standard, is a 1 kHz square wave signal in the range of +12 and −12 volts. The control pilot signal CP uses its voltage to define the state of the charging transaction. If the 1 kHz square wave signal positive voltage is +12 volts, this indicates State A, that an EV is not connected. If the 1 kHz square wave signal positive voltage is +9 volts and the minus voltage as −12 volts, this indicates State B, that an EV is connected, but is not ready to receive a charge. The SAE J1772 standard specifies that the 1 kHz square wave signal positive voltage of +6 volts and the minus voltage as −12 volts, indicates State C, that the EV is ready to accept the charge. The EV performs this signaling to indicate the EVSE that the charging handle 150 is connected and the EV is ready to receive the charge.

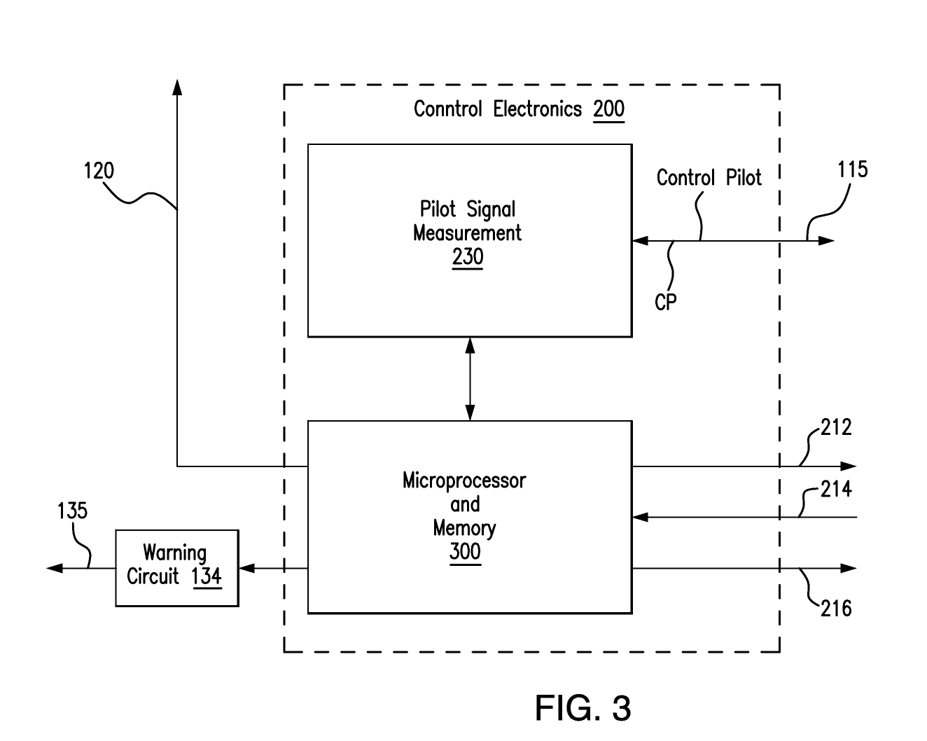

FIG. 3 is a functional block diagram of an example control electronics 200 in the EVSE, including the pilot signal measurement module 230 and a microprocessor and memory 300. The microprocessor may be programmed and its associated memory may contain program instructions which, when executed by the microprocessor, carry out functions, for example, of the shorted cable detection circuit 235, the MUX selection 238, and the warning circuit 134. The microprocessor may receive CP signal status from the pilot signal measurement module 230, indicating whether an EV is connected to the cable 105. The microprocessor may be connected over line 212 to the impedance measurement circuit 140 to control the impedance measurement circuit 140 to conduct impedance measurements only during periods when the charging cable 105 and its charging handle 150 are not connected to an EV. The microprocessor may be programmed to receive the alert signal on line 214 and in response, send a protection signal over line 120 to the contactor or relay 130, to prevent closure of the contacts in the contactor or relay 130. The microprocessor may be programmed to output multiplexer selection signals on line 216 to enable sequentially performing an impedance test between different pairs of the conductors L1, L2/N and ground G, while the charging cable is not connected to an EV. The signal on line 216 may be generated when the pilot signal measurement circuit 230 indicates that there is no connection to an EV. The microprocessor may be programmed to cause a warning to be displayed and the display of the identity of the shorted conductors, for appropriate maintenance action by the owner of the EVSE. The microprocessor may be programmed to display the shorted cable detection status for every combination of conductors tested, to indicate the precise problem to the owner or operator of the EVSE. The microprocessor may be programmed to repeatedly test the impedance of the conductors of the cable 105 and record the detection status for every pair of the conductors as a maintenance history. The control electronics 200 may reuse an existing microprocessor and memory in the EVSE, with little or no modification required to the EVSE control electronics.

Although specific example embodiments of the invention have been disclosed, persons of skill in the art will appreciate that changes may be made to the details described for the specific example embodiments, without departing from the spirit and the scope of the invention.

1. A method for detecting a shorted charging cable of an electric vehicle charging station, comprising:
(a) sensing that a charging cable of an electric vehicle charging station is not connected to an electric vehicle;
(b) performing an impedance test between conductors of the charging cable while the charging cable is not connected to an electric vehicle; and
(c) preventing closure of a contactor between a source of electrical power and the conductors of the charging cable in response to detecting a short between the conductors.

2. The method for detecting a shorted charging cable of an electric vehicle charging station of claim 1, further comprising:
(d) outputting a warning signal in response to detecting a short between the conductors; and
(e) disabling the impedance test in response to receiving a signal indicating that the charging cable has become connected to an electric vehicle.

3. The method for detecting a shorted charging cable of an electric vehicle charging station of claim 1, further comprising:
sequentially performing an impedance test between different pairs of the conductors of the charging cable while the charging cable is not connected to an electric vehicle.

4. The method for detecting a shorted charging cable of an electric vehicle charging station of claim 1, wherein the contactor is protected from potential welding of its contacts by preventing closure of the contactor in response to detecting a short between the conductors.

5. The method for detecting a shorted charging cable of an electric vehicle charging station of claim 1, further comprising:
identifying any shorted conductors for appropriate maintenance action.

6. The method for detecting a shorted charging cable of an electric vehicle charging station of claim 1, further comprising:
repeating performance of an impedance test between conductors of the charging cable at intervals over time; and
recording results of the impedance tests for pairs of the conductors tested.

7. The method for detecting a shorted charging cable of an electric vehicle charging station of claim 1, wherein the signal indicating that the charging cable has become connected to an electric vehicle, is a control pilot signal operating according to SAE J1772 standards for Electric Vehicle Supply Equipment (EVSE).

8. A circuit for detecting a shorted charging cable of an electric vehicle charging station, comprising:
(a) a sensing circuit in an electric vehicle charging station, the sensing circuit being coupled to a control pilot line of the electric vehicle charging station, the sensing circuit being configured to receive a control pilot signal indicating that a charging cable of the electric vehicle charging station is not connected to an electric vehicle;
(b) an impedance measurement circuit in the electric vehicle charging station, the impedance circuit being coupled to the sensing circuit, the impedance measurement circuit being configured to perform an impedance test between conductors of the charging cable while the charging cable is not connected to an electric vehicle; and
(c) a protection circuit in the electric vehicle charging station, the protection circuit being coupled to the impedance circuit, the protection circuit being configured to prevent closure of a contactor between a source of electrical power and the conductors of the charging cable in response to the impedance measurement circuit detecting a short between the conductors.

9. The circuit for detecting a shorted charging cable of an electric vehicle charging station of claim 8, further comprising:
(d) a warning circuit in the electric vehicle charging station, the warning circuit being coupled to the protection circuit, the warning circuit being configured to output a warning signal in response to detecting a short between the conductors; and
(e) the sensing circuit being further configured to disable the impedance measurement circuit in response to receiving a control pilot signal indicating that the charging cable has become connected to an electric vehicle.

10. The circuit for detecting a shorted charging cable of an electric vehicle charging station of claim 8, further comprising:
a multiplexer circuit in the electric vehicle charging station, the multiplexer circuit being configured to sequentially connect the impedance measurement circuit between different pairs of the conductors of the charging cable while the charging cable is not connected to an electric vehicle.

11. The circuit for detecting a shorted charging cable of an electric vehicle charging station of claim 8, wherein the contactor is protected from potential welding of its contacts by preventing closure of the contactor in response to detecting a short between the conductors.

12. The circuit for detecting a shorted charging cable of an electric vehicle charging station of claim 8, wherein shorted conductors are identified for appropriate maintenance action.

13. The circuit for detecting a shorted charging cable of an electric vehicle charging station of claim 8, wherein performance of an impedance test between conductors of the charging cable is repeated at intervals over time; and
control electronics in the electric vehicle charging station, the control electronics being configured to record results of the impedance tests for pairs of the conductors tested.

14. The circuit for detecting a shorted charging cable of an electric vehicle charging station of claim 8, wherein the control pilot signal operates according to standard SAE J1772 for Electric Vehicle Supply Equipment (EVSE).
